(19) United States
(12) Patent Application Publication
(10) Pub. No.: US 2013/0344697 A1
(43) Pub. Date: Dec. 26, 2013

(54) METHOD OF FABRICATING NMOS DEVICES

(71) Applicant: SHANGHAI HUALI MICROELECTRONICS CORPORATION, Shanghai (CN)

(72) Inventor: Qiang XU, Shanghai (CN)

(73) Assignee: SHANGHAI HUALI MICROELECTRONICS CORPORATION, Shanghai (CN)

(21) Appl. No.: 13/730,446

(22) Filed: Dec. 28, 2012

(30) Foreign Application Priority Data
Jun. 21, 2012 (CN) 201210209073.2

(51) Int. Cl. H01L 21/311

(52) U.S. Cl. CPC H01L 21/31116
USPC 438/694

(57) ABSTRACT

A method of fabricating n-channel metal-oxide-semiconductor (NMOS) devices is disclosed, the method including: providing a substrate having a plurality of NMOS structures formed thereon; depositing a silicon nitride layer having a high tensile stress over the substrate; and sequentially exposing and dry etching a plurality of portions of the silicon nitride layer in an order of channel lengths of the plurality of NMOS structures such that each portion of the etched silicon nitride layer has a thickness proportional to the channel length of its corresponding NMOS structure. Compared to a conventional method, the above fabrication method of NMOS devices can achieve uniform performance adjustment of NMOS devices after a silicon nitride layer with a high tensile stress is deposited.

### CROSS-REFERENCES TO RELATED APPLICATIONS

This application claims the priority of Chinese patent application number 201210209073.2, filed on Jun. 21, 2012, the entire contents of which are incorporated herein by reference.

### TECHNICAL FIELD

The present invention relates to semiconductor fabrication, and more particularly, to a method of fabricating n-channel metal-oxide-semiconductor (NMOS) devices.

### BACKGROUND

With the development of semiconductor fabrication processes, critical dimension of integrated circuits (ICs) has been consistently reduced. In order to improve the performance of semiconductor devices, stress engineering technology has been widely employed in semiconductor processes to enhance the carrier electric mobility. For example, the contact etch stop layer (CESL) process used in the fabrication of n-channel metal-oxide-semiconductor (NMOS) devices is a commonly used stress engineering technology.

In such CESL process, during the deposition of a CESL thin film, a high stress is generated in the thin film by adjusting deposition parameters and the stress is thereafter transferred to the channel of the device to improve the carrier electric mobility therein. Specifically, for example, in the fabrication of an NMOS device, application of the CESL process can result in a CESL thin film with compressive stress, which can generate a tensile stress respectively in the channel of the NMOS device. As tensile stress along a channel direction is capable of enhancing the electric mobility of the NMOS device, the performance of the NMOS device will be improved. Production tests have proved that a more than 10% increase of an NMOS device's performance can be obtained by depositing a silicon nitride thin film having a high tensile stress.

However, based on production experience, the inventor of the present invention has found that performance-enhancing effect of the conventional CESL process varies for NMOS devices with different channel lengths. Just as shown in FIG. 1, this beneficial effect of the process weakens with an increase of the channel length.

Currently, in the product fabrication, the factor of channel length is generally taken into account early in the stage of layout design so as to work out a special structure to solve this problem. Moreover, in most cases, the designed layout will undergo verifications and corrections before it is put into use. Undoubtedly, such an approach has dramatically increased the time and cost in product research, development and fabrication.

### SUMMARY OF THE INVENTION

The present invention addresses the above issue by presenting a method of fabricating an n-channel metal-oxide-semiconductor (NMOS) device, which can improve the uniformity of NMOS devices' performance by proportionating thicknesses of portions of the silicon nitride layer to the lengths of the channels.

To achieve the above objective, the present invention provides a method of fabricating an n-channel metal-oxide-semiconductor (NMOS) device, the method including the steps of:

providing a substrate having a plurality of NMOS structures formed thereon;

depositing a silicon nitride layer having a high tensile stress over the substrate; and

sequentially exposing and dry etching a plurality of portions of the silicon nitride layer in an order of channel lengths of the plurality of NMOS structures such that each portion of the etched silicon nitride layer has a thickness proportional to the channel length of its corresponding NMOS structure.

Optionally, the silicon nitride layer is deposited by a plasma enhanced chemical vapor deposition (PECVD) method.

Optionally, the silicon nitride layer has a thickness of 300 Å to 800 Å.

Optionally, the silicon nitride layer has a stress of 0.7 GPa to 2.0 GPa.

Optionally, the order of the channel lengths of the plurality of NMOS structures is an order from a shortest channel length to a longest channel length, or an order from a longest channel length to a shortest channel length.

Optionally, dry etching the plurality of portions of the silicon nitride layer uses an etchant gas with low fluorine and carbon contents.

Optionally, the etchant gas used in dry etching the plurality of portions of the silicon nitride layer is any one, or a combination of more than one, selected from the group consisting of carbon tetrafluoride (CF₄), octafluorocyclobutane (C₄F₈) and perfluorinated butadiene (C₄F₆).

Optionally, the method further includes depositing a pre-metal dielectric (PMD) layer.

Compared to the prior art, by taking into full account the relationship between the channel lengths and the carrier mobility enhancement effects caused by the silicon nitride layer, in the present invention, the silicon nitride layer is exposed and dry etched according to the channel lengths of the corresponding NMOS devices to proportionate thicknesses of portions of the etched silicon nitride layer to the channel lengths so as to achieve uniform performance adjustment of the NMOS devices.

### BRIEF DESCRIPTION OF THE DRAWINGS

FIG. 1 illustrates the relationship of the performance of an NMOS device to the channel length of the NMOS device.

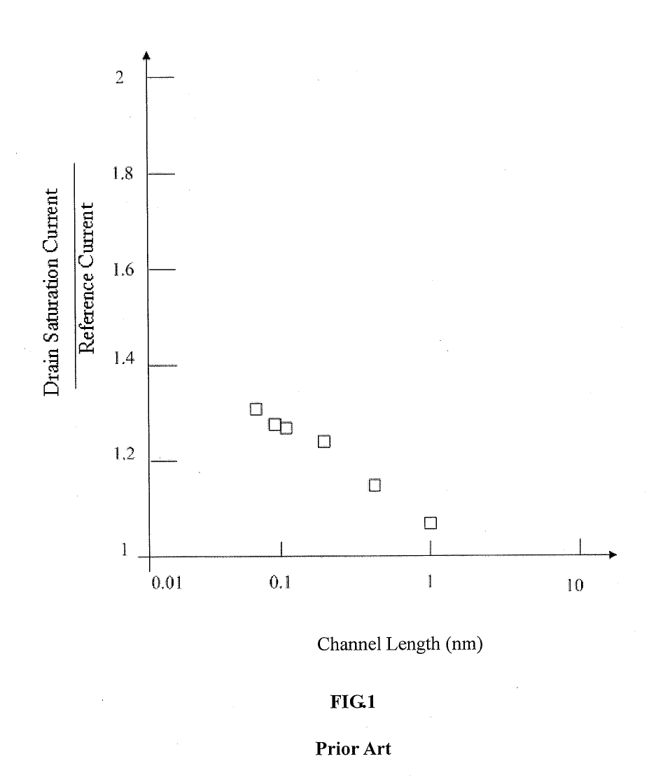

FIG. 2 is a flow chart illustrating a method of fabricating NMOS devices constructed according to an embodiment of the present invention.

FIG. 3 is a cross sectional view of NMOS devices formed in the step S2 of FIG. 2.

FIGS. 4 to 5 are cross sectional views of NMOS devices formed according to an embodiment of the step S3 of FIG. 2.

### DETAILED DESCRIPTION

After a silicon nitride layer with a high tensile stress is deposited over a waferin the present invention, the silicon nitride layer will be exposed and dry etched according to the channel lengths of the NMOS devices to make sure that the longer the channel of the NMOS device is, the thicker its corresponding silicon nitride layer is, so as to achieve uniform performance adjustment of the NMOS devices.

The fabrication method of NMOS devices of the present invention will be described and specified below with reference to accompanying drawings and specific exemplary embodiments.

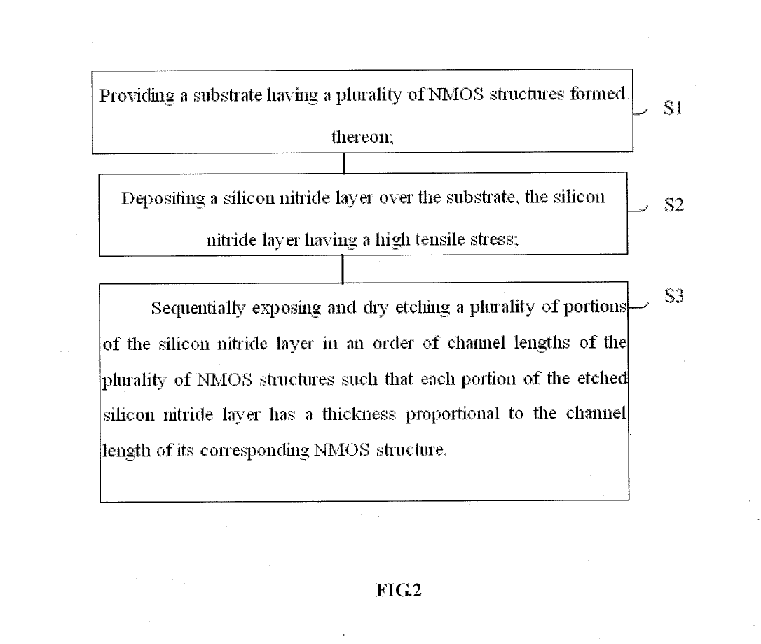

Referring to FIG. 2, in an embodiment, the method of fabricating NMOS devices of the present invention includes the steps of:

S1: providing a substrate having a plurality of NMOS structures formed thereon;

S2: depositing a silicon nitride layer over surface of the substrate, the silicon nitride layer having a high tensile stress;

S3: sequentially exposing and dry etching a plurality of portions of the silicon nitride layer in an order of channel lengths of the plurality of NMOS structures such that each portion of the etched silicon nitride layer has a thickness proportional to the channel length of its corresponding NMOS structure.

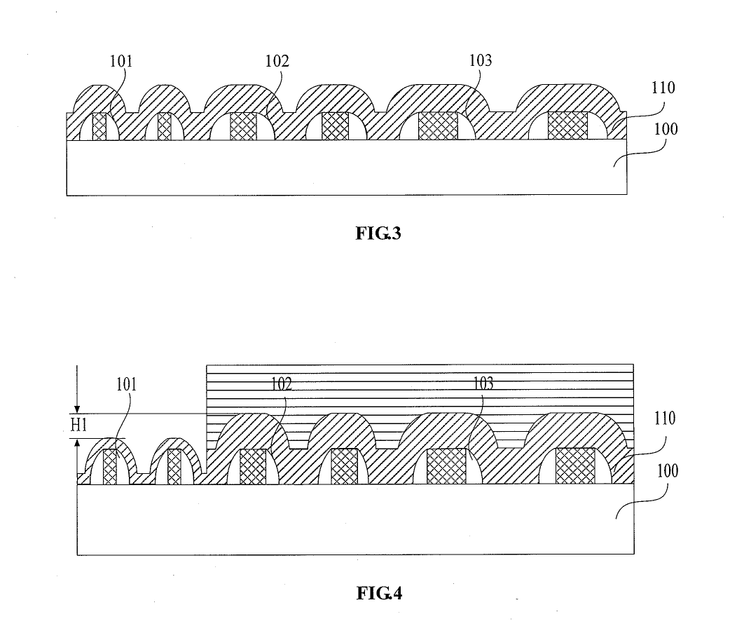

Specifically, reference is first made to FIG. 3 which shows that a silicon nitride layer 110 is deposited on a substrate 100 having a plurality of NMOS structures formed thereon. The silicon nitride layer 110 has a thickness of 300 Å to 800 Å and may be deposited by a plasma enhanced chemical vapor deposition (PECVD) method. Moreover, the silicon nitride layer 110 has a high tensile stress within the range of 0.7 GPa to 2.0 GPa.

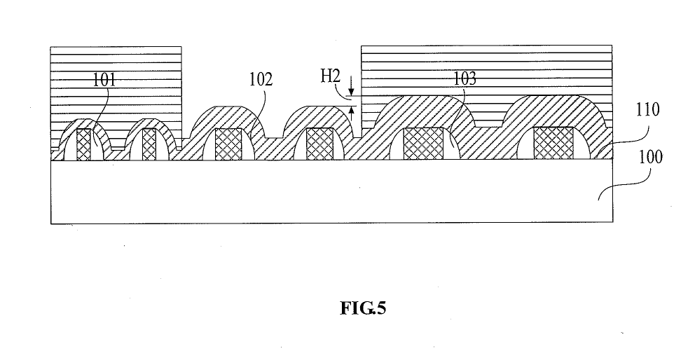

As shown in FIG. 4, NMOS structures, namely NMOSs 101, NMOSs 102 and NMOSs 103, having channels with different lengths are provided on the substrate 100. The deposited silicon nitride layer may be exposed and dry etched in the order of the channel lengths of the NMOS structures, from a shortest channel length to a longest channel length, or alternatively, from a longest channel length to a shortest channel length.

Specifically, at least two exposure-and-dry-etching processes are applied to the silicon nitride layer 110.

In a specific embodiment, as shown in FIG. 4, in the order of the channel lengths of the NMOS structures from a shortest channel length to a longest channel length, an exposure-and-dry-etching process is first applied to the portion of the silicon nitride layer 110 above the NMOSs 101 whose channel length is shortest among those of the three kinds of NMOS structures to reduce the thickness of the portion by H1; next, as shown in FIG. 5, another exposure-and-dry-etching process is applied to the portion of the silicon nitride layer 110 above the NMOSs 102 whose channel length is the second shortest to reduce the thickness of the portion by H2, which is greater than H1; and the portion of the silicon nitride layer 110 above the NMOSs 103 whose channel length is longest may not be exposed and etched, i.e., the thickness of the portion may not be further adjusted so as to keep the original value. As a result, when the mask layer is removed, the silicon nitride layer 110 over the substrate 110 will have different thicknesses in different portions, and its thickness is distributed in such a manner that it corresponds to the length of channels of the NMOS structure and is greater in a portion over a longer channel. As the deposited silicon nitride layer 110 has a high tensile stress which can be transferred to the channel to improve the mobility of carriers therein and a higher stress can affect a greater number of carriers, a thicker portion of the silicon nitride layer 110 which generates a higher stress is able to adjust the performance of an NMOS structure with a longer channel which holds more carriers.

An etchant gas with low fluorine and carbon contents, such as any one or a combination of more than one selected from the group consisting of carbon tetrafluoride (CF₄), octafluorocyclobutane (C₄F₈) and perfluorinated butadiene (C₄F₆), is used in the aforementioned dry-etching processes.

In another specific embodiment, after step S3, the method may further include depositing a pre-metal dielectric (PMD) layer.

Compared to the prior art, by taking into full account the relationship between the channel lengths and the carrier mobility enhancement effects caused by the silicon nitride layer in the method of the present invention, the silicon nitride layer is exposed and dry etched according to the channel lengths of the corresponding NMOS devices to proportionate thicknesses of portions of the etched silicon nitride layer to the channel lengths so as to achieve uniform performance adjustment of the NMOS devices.

While preferred embodiments have been presented in the foregoing description of the invention, they are not intended to limit the invention in any way. Those skilled in the art can make various modifications and variations to the technical scheme of the present invention based on the methods and technical contents disclosed above without departing from the spirit or scope of this invention. Thus, it is intended that the present invention covers all such modifications and variations, as well as their equivalents.

What is claimed is:

1. A method of fabricating n-channel metal-oxide-semiconductor (NMOS) devices, the method comprising the steps of:
providing a substrate having a plurality of NMOS structures formed thereon;
depositing a silicon nitride layer having a high tensile stress over the substrate; and
sequentially exposing and dry etching a plurality of portions of the silicon nitride layer in an order of channel lengths of the plurality of NMOS structures such that each portion of the etched silicon nitride layer has a thickness proportional to the channel length of its corresponding NMOS structure.

2. The method according to claim 1, wherein the silicon nitride layer is deposited by a plasma enhanced chemical vapor deposition method.

3. The method according to claim 1, wherein the silicon nitride layer has a thickness of 300 Å to 800 Å.

4. The method according to claim 1, wherein the silicon nitride layer has a stress of 0.7 GPa to 2.0 GPa.

5. The method according to claim 1, wherein the order of channel lengths of the plurality of NMOS structures is an order from a shortest channel length to a longest channel length, or an order from a longest channel length to a shortest channel length.

6. The method according to claim 1, wherein the plurality of portions of the silicon nitride layer are dry etched by using an etchant gas with low fluorine and carbon contents.

7. The method according to claim 6, wherein the etchant gas is any one, or a combination of more than one, selected from the group consisting of carbon tetrafluoride, octafluorocyclobutane and perfluorinated butadiene.

8. The method according to claim 1, further comprising a step of depositing a pre-metal dielectric layer.
